(19) United States
(12) Patent Application Publication
(10) Pub. No.: US 2015/0355235 A1
(43) Pub. Date: Dec. 10, 2015

(54) PROBE AND METHOD FOR MANUFACTURING THE PROBE

(71) Applicant: MPI CORPORATION, CHU-PEI CITY (TW)

(72) Inventors: Yu-Chen HSU, CHU-PEI CITY (TW); Shao-Lun WEI, CHU-PEI CITY (TW); Horng-Kuang FAN, CHU-PEI CITY (TW)

(21) Appl. No.: 14/732,104

(22) Filed: Jun. 5, 2015

(30) Foreign Application Priority Data
Jun. 6, 2014 (TW) 103119775
Mar. 11, 2015 (TW) 104107747

(51) Int. Cl. G01R 1/073; B81C 1/00; G01R 1/067

(52) U.S. Cl. CPC G01R 1/07314; G01R 1/06716; B81C 1/00373; B81C 1/00611

(57) ABSTRACT

A probe for a probe head having lower and upper dies includes a main portion, a conductive portion stacked on at least a part of the main portion, an attachment layer covering the main portion and the conductive portion, a skin effect layer covering the attachment layer, and a stopping portion for being abutted against the lower or upper die. The main portion includes a first material. The conductive portion includes a second material. The skin effect layer includes a third material. The electrical conductivity of the third material is greater than that of the second material. The electrical conductivity of the second material is greater than that of the first material. The hardness of the first material is greater than that of the second material, and also greater than that of the third material.

### BACKGROUND OF THE INVENTION

1. Field of the Invention

The present invention relates to probes and more particularly, to a probe which is improved in current carrying capacity, and a method for manufacturing the probe.

2. Description of the Related Art

Upon testing a wafer, a tester contacts the wafer by means of a probe card for transmitting testing signals to the wafer and obtaining electrical signals from the wafer. The probe card usually comprises a plurality of probes with precise measurements. For the purpose of testing the wafer, the probes contact the small-sized contacts, such as pads or bumps, on the device under test (hereinafter referred to as the “DUT”) for transmitting the testing signals from the tester to the DUT in coordination with the programs of controlling the probe card and the tester. Because the intervals between the contacts on the wafer are getting shorter and shorter, it is more and more popular to manufacture the probes for fine pitch applications by micro-electro-mechanical systems (MEMS) technology. The commercially available MEMS probes include pogo pins, vertical buckling probes and C-shaped probes, which are manufactured by batch and mass production available by MEMS technology.

The vertical buckling probe has a simple configuration and can provide sufficient elasticity to adapt to uneven surfaces on the wafer under test during probing. When the wafer is probed by a plurality of MEMS probes at the same time, the MEMS probes are a little deformed by the contact force between the wafer and the probes, thereby ensuring positive electrical connections between the MEMS probes and the contacts. Because of having sufficient elasticity, the MEMS probes will not be fractured when pressed by external force. In the situation that the probes and the contacts on the wafer have stable contact resistance therebetween, the results of testing the wafer is relatively more reliable. However, in order that the buckling probe can offer sufficient elasticity, parts of the body of the probe are provided with relatively smaller cross-sections, to which relatively greater stress are concentrated. When the testing current is transmitted through the buckling probe, the parts having relatively smaller cross-sections will be relatively more heated, thereby relatively more liable to be fractured by heat. Therefore, the current carrying capacity of the buckling probe depends on the parts having relatively smaller cross-sections.

### SUMMARY OF THE INVENTION

The present invention provides a vertical buckling probe which is improved in current carrying capacity.

The present invention provides a probe head having a vertical buckling probe which is improved in current carrying capacity.

The present invention provides a probe which is improved in current carrying capacity.

The present invention provides a method for manufacturing the aforesaid probe.

The vertical buckling probe of the present invention comprises a main portion, a conductive portion and a reinforcing layer. The main portion has a tip, a body connected with the tip, and a tail connected with the body. The main portion comprises a first material. The conductive portion is attached to at least a part of the body, and comprises a second material. The reinforcing layer covers a part of the conductive portion, and comprises a third material. The electrical conductivity of the second material is greater than the electrical conductivity of the third material. The hardness of the second material is less than the hardness of the third material.

The probe head of the present invention is adapted for being used in a probe card, and comprises a lower die, an upper die and the aforesaid probe. The lower die has at least one lower hole. The upper die is located on the lower die, and has at least one upper hole. The tip and the tail of the aforesaid probe are inserted in the lower hole and the upper hole, respectively.

The probe of the present invention is adapted for being used in a probe head having a lower die and an upper die. The probe comprises a main portion, a conductive portion, an attachment layer, a skin effect layer, and a stopping portion. The conductive portion is stacked on at least a part of the main portion. The attachment layer covers the main portion and the conductive portion. The skin effect layer covers the attachment layer. The main portion comprises a first material. The conductive portion comprises a second material. The skin effect layer comprises a third material. The electrical conductivity of the third material is greater than the electrical conductivity of the second material. The electrical conductivity of the second material is greater than the electrical conductivity of the first material. The hardness of the first material is greater than the hardness of the second material. The hardness of the first material is greater than the hardness of the third material. The stopping portion is abutted against the lower die or the upper die.

The method for manufacturing a probe of the present invention comprises the steps of: forming a main portion and a conductive portion which is stacked on at least a part of the main portion; forming an attachment layer which covers the main portion and the conductive portion; and forming a skin effect layer which covers the attachment layer. Wherein, the main portion comprises a first material; the conductive portion comprises a second material; the skin effect layer comprises a third material; the electrical conductivity of the third material is greater than the electrical conductivity of the second material; the electrical conductivity of the second material is greater than the electrical conductivity of the first material; the hardness of the first material is greater than the hardness of the second material; the hardness of the first material is greater than the hardness of the third material.

Based on the above disclosures, the buckling probe of the present invention has desired mechanical strength resulted from the main portion, so that the probe is prevented from permanent deformation during the testing process. Besides, the conductive portion improves the current carrying capacity of the probe, so that the probe is less possibly damaged by heat resulted from large currents. In addition, the reinforcing layer, which covers a part of the conductive portion, is effective in preventing the conductive portion from oxidation, so that the electrical conductivity of the conductive portion will last. On the other hand, the reinforcing layer is effective in increasing the structural strength of the probe, so that the probe has relatively greater wear resistance and mechanical strength so as to have relatively longer life time. As to the probe of the present invention and the method for manufacturing the probe, the probe has the skin effect layer which may cover the conductive portion partially or completely, or cover the main portion and the conductive portion partially or completely, resulting in additional path for electrical currents. Besides, the skin effect layer can be formed around periphery of the main portion and the conductive portion after the main portion and the conductive portion are formed, so that the manufacturing process of the probe can be simplified.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1A is an exploded perspective view of a vertical buckling probe according to an embodiment of the present invention;

FIG. 1B is an assembled perspective view of the vertical buckling probe shown in FIG. 1A;

FIG. 2 is a perspective view of a vertical buckling probe according to another embodiment of the present invention;

FIG. 3A and FIG. 3B are perspective views of vertical buckling probes according to two other embodiments of the present invention;

FIG. 4 is a schematic view of a probe head according to an embodiment of the present invention;

FIG. 5A is a schematic view of a probe according to an embodiment of the present invention;

FIG. 5B is a sectional view taken along the line 12B-12B in FIG. 5A;

FIG. 5C is an enlarged sectional view taken along the line 12C-12C in FIG. 5A;

FIG. 6 is an enlarged sectional view of a probe according to an embodiment of the present invention;

FIG. 7A is a schematic view of a probe according to an embodiment of the present invention;

FIG. 7B is a sectional view taken along the line 14B-14B in FIG. 7A;

FIG. 7C is an enlarged sectional view taken along the line 14C-14C in FIG. 7A;

FIG. 8A is a schematic view of a probe according to an embodiment of the present invention;

FIG. 8B is a sectional view taken along the line 15B-15B in FIG. 8A;

FIG. 8C is an enlarged sectional view taken along the line 15C-15C in FIG. 8A;

FIG. 9A is a schematic view of a probe according to an embodiment of the present invention;

FIG. 9B is a sectional view taken along the line 16B-16B in FIG. 9A;

FIG. 9C is an enlarged sectional view taken along the line 16C-16C in FIG. 9A;

FIG. 10A is a schematic view of a probe according to an embodiment of the present invention;

FIG. 10B is a sectional view taken along the line 17B-17B in FIG. 10A;

FIG. 10C is an enlarged sectional view taken along the line 17C-17C in FIG. 10A;

FIGS. 11A-11D are schematic views showing four alternated shapes of the probe shown in FIG. 5A;

FIGS. 12A-12H are schematic transverse sectional views showing the steps of a method for manufacturing a probe according to an embodiment of the present invention;

FIGS. 13A-13L are schematic transverse sectional views showing the steps of a method for manufacturing a probe according to an embodiment of the present invention;

FIGS. 14A-14L are schematic longitudinal sectional views of FIGS. 13A-13L;

FIG. 15 is a schematic view showing an intermediate structure adopted in a method for manufacturing a probe according to an embodiment of the present invention;

FIG. 16 is a sectional view of a probe according to another embodiment of the present invention; and

FIG. 17 is a sectional view of a probe according to still another embodiment of the present invention.

### DETAILED DESCRIPTION OF THE INVENTION

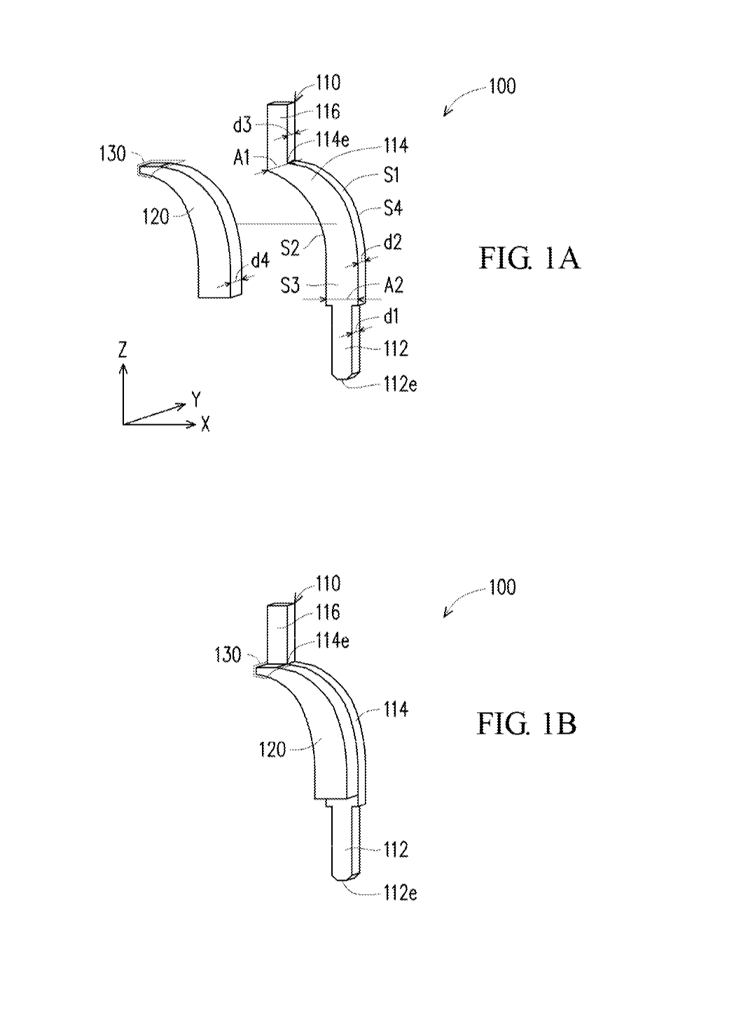

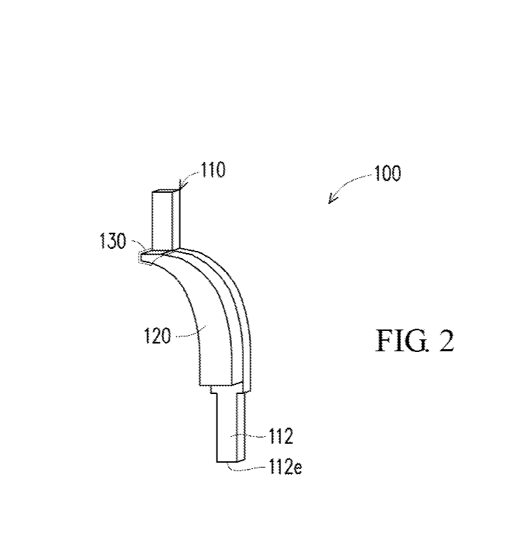

FIG. 1A is an exploded perspective view of a vertical buckling probe according to an embodiment of the present invention. FIG. 1B is an assembled perspective view of the vertical buckling probe shown in FIG. 1A. Referring to FIGS. 1A and 1B, a vertical buckling probe 100 in this embodiment comprises a main portion 110, a conductive portion 120, and a reinforcing layer 130. The main portion 110 has a tip 112, a body 114 connected with the tip 112, and a tail 116 connected with the body 114. The tip 112 is connected to an end of the body 114, and the tail 116 is connected to the other end of the body 114. The body 114 is curved and has a section having cross-section areas gradually decreased in the direction from the tip 112 to the tail 116. An offset is provided between the tip 112 and the tail 116; therefore, the tip 112 and the tail 116 are not aligned along a same vertical axis. Specifically speaking, the tip 112 and the tail 116 are not aligned along a same axis in the Z-axis shown in FIG. 1A. The main portion 110 comprises a first material for providing sufficient mechanical strength to the vertical buckling probe, so that the vertical buckling probe is prevented from permanent deformation in the testing process. The conductive portion 120 is attached to at least a part of the body 114, and comprises a second material such as silver (Ag) or copper (Cu). The reinforcing layer 130 covers a part of the conductive portion 120, and comprises a third material. The electrical conductivity of the second material is greater than the electrical conductivity of the third material. The hardness of the second material is less than the hardness of the third material. Referring to FIGS. 1A and 1B again, the tip 112, the body 114 and the tail 116 have equal thickness. In other words, the thickness d1 of the tip 112 is equal to the thickness d2 of the body 114, and also equal to the thickness d3 of the tail 116. Besides, the assembly of the conductive portion 120 and the body 114 has larger cross-sections on X-Y planes in FIG. 1A than the body 114. As to this embodiment, the contour of the conductive portion 120 is matched with the contour of the body 114, and the conductive portion 120 and the body 114 have equal width. Referring to FIG. 1A again, the cross-section areas of the body 114 are gradually decreased in the direction from the tip 112 to the tail 116. That is, the cross-section area A2 is larger than the cross-section area A1. Specifically speaking, the smallest cross-section of the body 114 is located at an end 114e of the body 114, which is connected with the tail 116. In other words, the smallest cross-section area of the body 114 is provided at the location denoted by reference numeral A1.

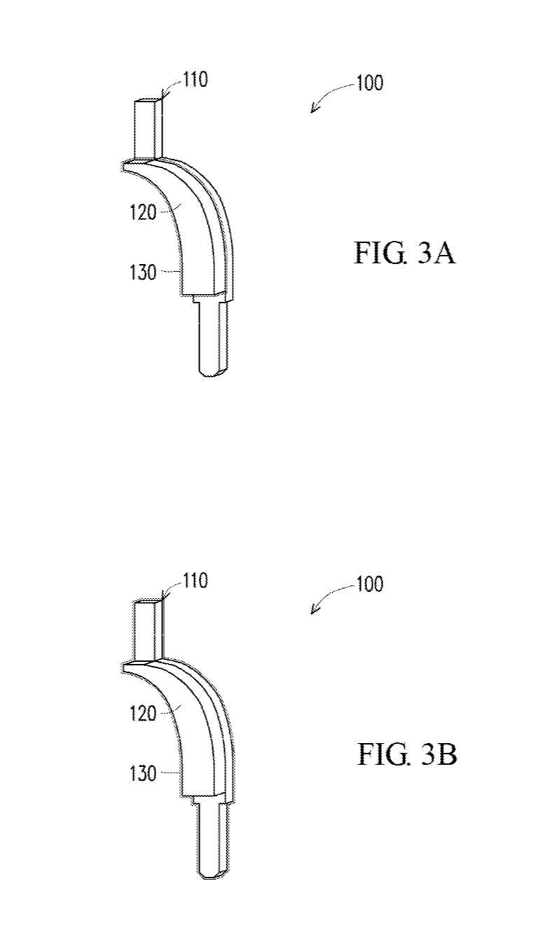

The configuration design of the tip 112 may be changed, depending on the practical demands. For example, the tip 112 may have the shape as shown in FIGS. 1A and 1B or as shown in FIG. 2.

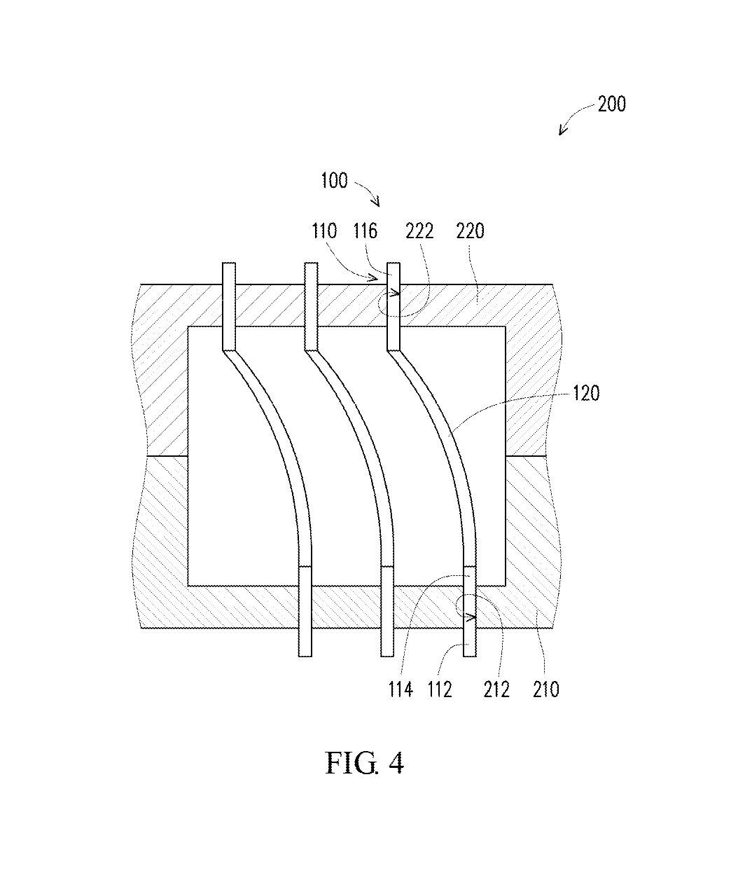

FIG. 3A and FIG. 3B are perspective views of vertical buckling probes according to two other embodiments of the present invention. Referring to FIG. 3A, the reinforcing layer 130, which covers the whole conductive portion 120, relieves the disadvantages of the material of the conductive portion 120, which are of insufficient strength, liability to oxidation, and low melting point. Besides, the electrical conductivity of the conductive portion 120 will well last because of the reinforcing layer 130. Referring to FIG. 3B, the reinforcing layer 130, which covers the whole assembly of the main portion 110 and the conductive portion 120, not only prevents the conductive portion 120 from oxidation, but also reinforces the connection between the main portion 110 and the conductive portion 120, so that the vertical buckling probe 100 is more durable. Besides, the weight of the vertical buckling probe 100 is adjustable by adjusting the thickness of the reinforcing layer 130.

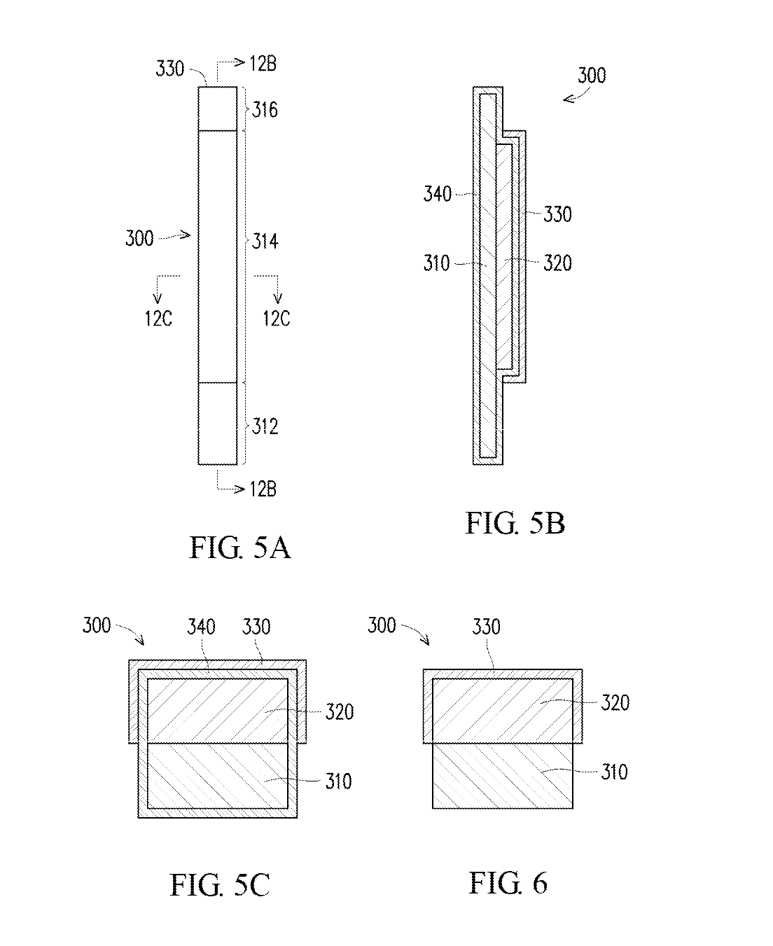

FIG. 4 is a schematic view of a probe head according to an embodiment of the present invention. Referring to FIG. 4, a probe head 200 in this embodiment, which is adapted for being used in a probe card, comprises a lower die 210, an upper die 220, and vertical buckling probes 100. The lower die 210 has at least one lower hole 212. The upper die 220 is located on the lower die 210, and has at least one upper hole 222. The tip 112 of each vertical buckling probe 100 is inserted through the lower hole 212, and the tail 116 is inserted through the upper hole 222. The wafer under test (not shown) is located below the tips 112. When probing the wafer, the vertical buckling probes 100 are elastically deformed by the contact force between the wafer and the probes, thereby maintaining positive electrical connections between the tips 112 of the vertical buckling probes 100 and the contacts on the wafer. When the testing of the wafer is finished and the contact force between the wafer and the probes is released, the vertical buckling probes 100 will be rebounded to the original shape by the elastic rebounding force thereof. Referring to FIGS. 1A, 1B and 4, the vertical buckling probe 100 has a stopping portion located at the juncture between the tip 112 and the body 114, where the cross-section of the tip 112 is smaller than the cross-section of the body 114. When the vertical buckling probe 100 is disposed to the upper die 220 and the lower die 210, the stopping portion is abutted against the lower die 210, thereby preventing the vertical buckling probe 100 from falling down through the lower hole 212 of the lower die 210 while the vertical buckling probe 100 is not forced and deformed. It is appreciated that in another embodiment the stopping portion may be not provided at the juncture between the tip 112 and the body 114, but the juncture of the tail 116 and the body 114. Such embodiment is structurally different from the embodiment shown in FIGS. 1A and 1B in that at the stopping portion the cross-section area of the tail 116 is larger than the cross-section area A2 of the body 114. When such vertical buckling probe is disposed to the upper die 220 and the lower die 210, the stopping portion is abutted against the upper die 220 at the outer side of the upper die 220, not in the space formed in the assembly of the upper die 220 and the lower die 210. In this way, the vertical buckling probe 100 is prevented from falling down through the upper hole 222 of the upper die 220 and the lower hole 212 of the lower die 210 while the vertical buckling probe 100 is not forced and deformed.

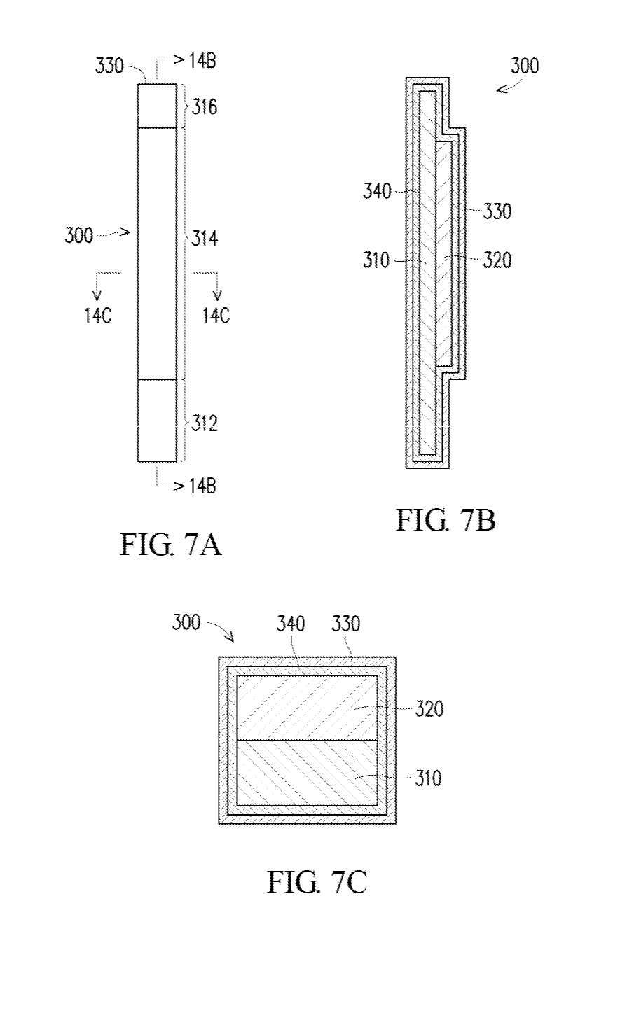

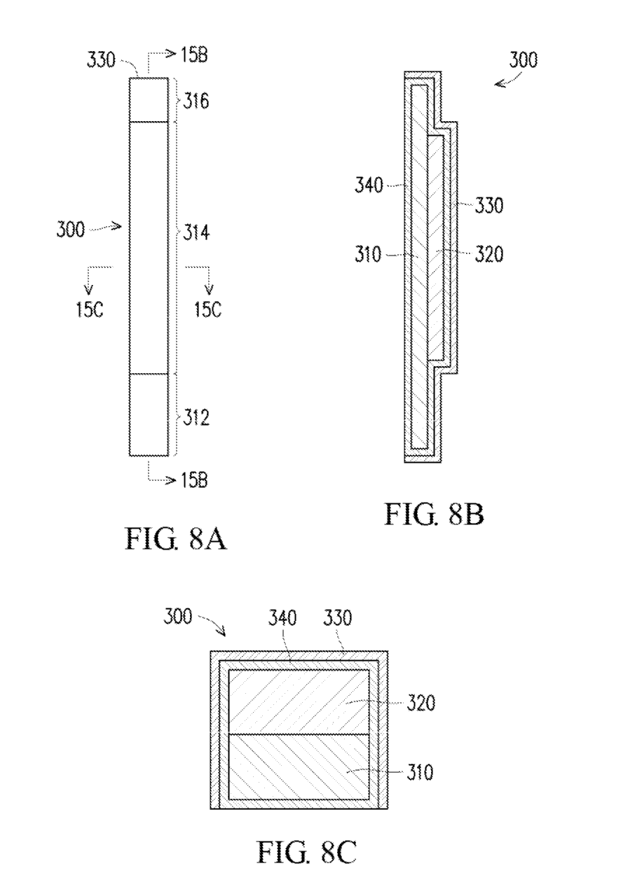

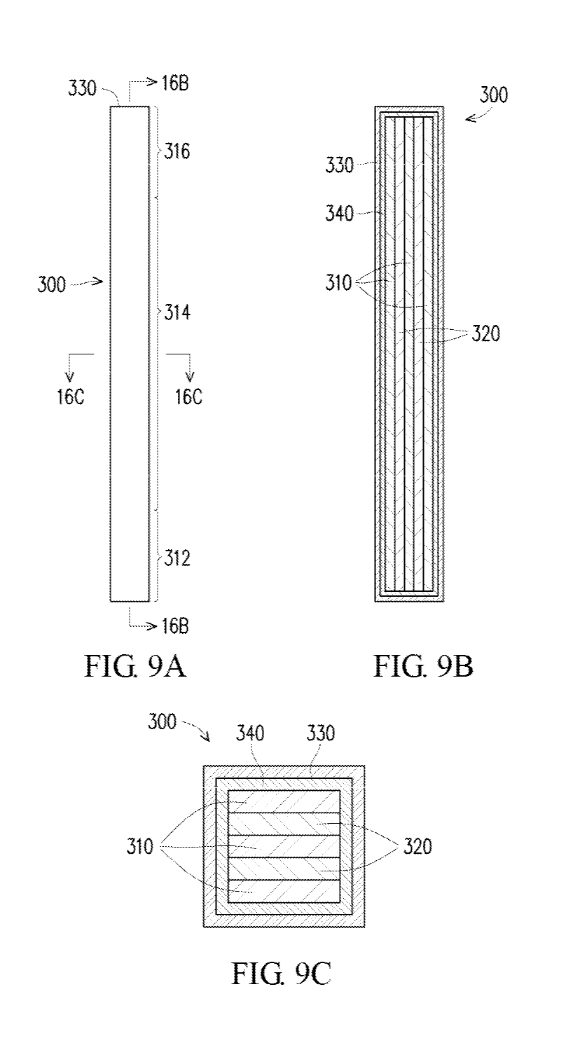

Referring to FIGS. 5A, 5B and 5C, a probe 300 in this embodiment comprises a main portion 310, a conductive portion 320, and a skin effect layer 330. The conductive portion 320 is stacked on at least a part of the main portion 310 for improving the current carrying capacity of the main portion 310 of probe 300. The skin effect layer 330 covers at least a part of the conductive portion 320 for providing additional path for electrical currents. Specifically speaking, the main portion 310 has a tip 312, a body 314 connected with the tip 312, and a tail 316 connected with the body 314. The conductive portion 320 is attached to at least a part of the body 314, such as the elastic section of the body 314. In other embodiments, the conductive portion 320 may be attached to at least a part of the tip 312 and at least a part of the body 314.

The main portion 310 comprises a first material such as palladium-cobalt alloy. The conductive portion 320 comprises a second material such as copper. The skin effect layer 330 comprises a third material such as silver. The electrical conductivity of the third material is greater than the electrical conductivity of the second material. The electrical conductivity of the second material is greater than the electrical conductivity of the first material. The hardness of the first material is greater than the hardness of the second material. The hardness of the first material is greater than the hardness of the third material.

The probe 300 further comprises an attachment layer 340 for increasing the attachment force between the skin effect layer 330 and the conductive portion 320. The attachment layer 340 is made of a material such as palladium or copper. The attachment layer 340 covers the main portion 310 and the conductive portion 320.

In this embodiment, the thickness of the conductive portion 320 is larger than twice of the thickness of the skin effect layer 330. The thickness of the main portion 310 is ranged from 15 μm (micrometer) to 40 μm. The thickness of the conductive portion 320 is ranged from 2 μm to 40 μm. The thickness of the skin effect layer 330 is ranged from 1 μm to 5 μm. The thickness of the attachment layer 340 is ranged from 0.1 μm to 3 μm.

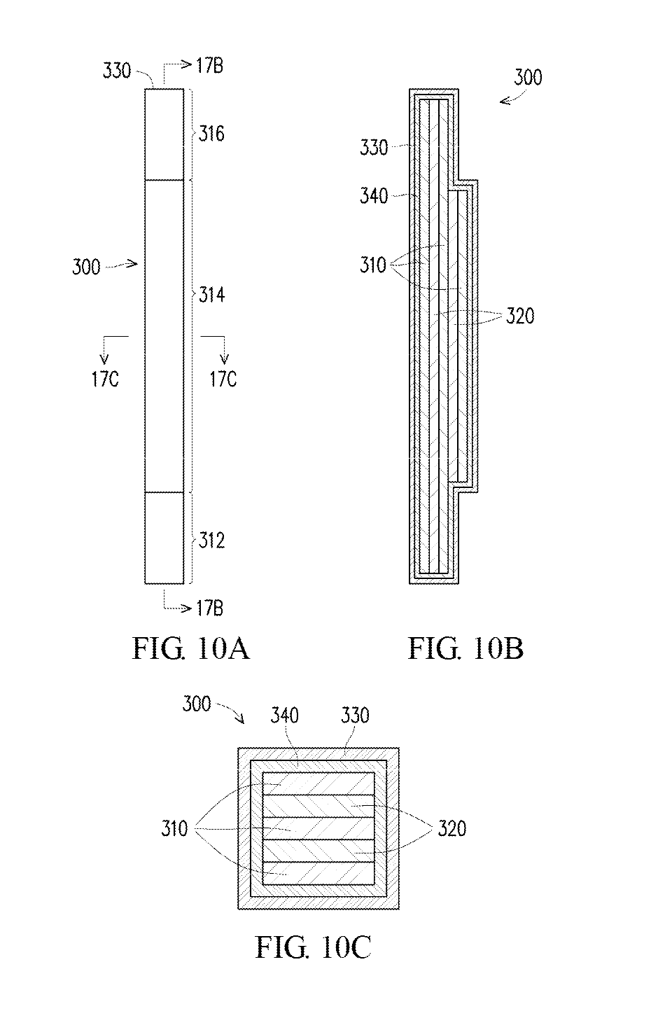

Referring to FIG. 6, a probe 300 in this embodiment shown in FIG. 6 is provided without such attachment layer 340 of the probe 300 shown in FIG. 5C, so that the skin effect layer 330 directly covers the conductive portion 320.

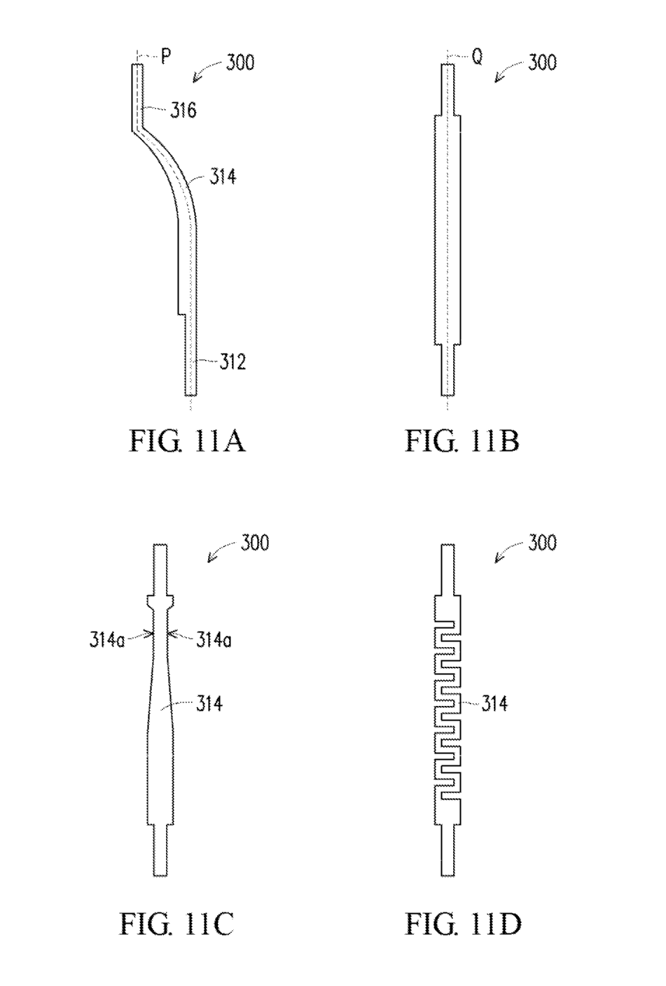

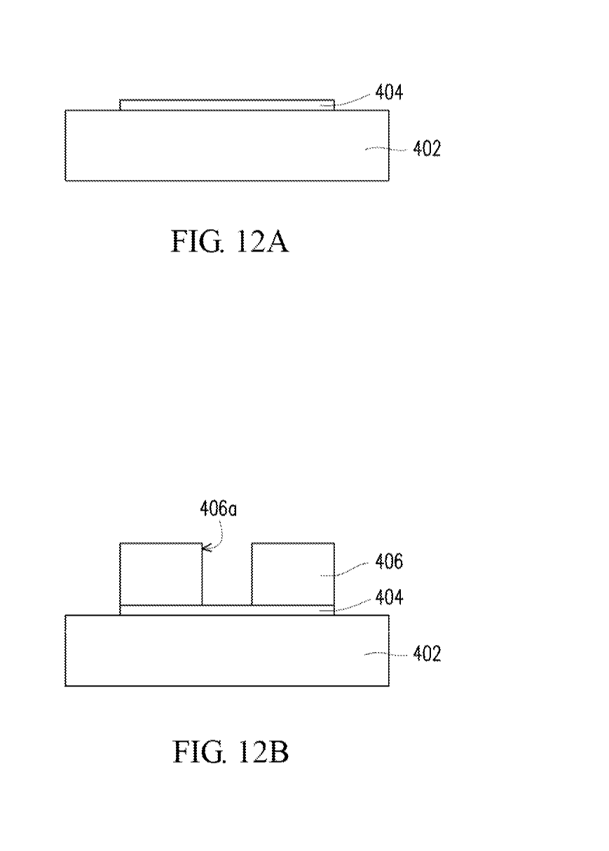

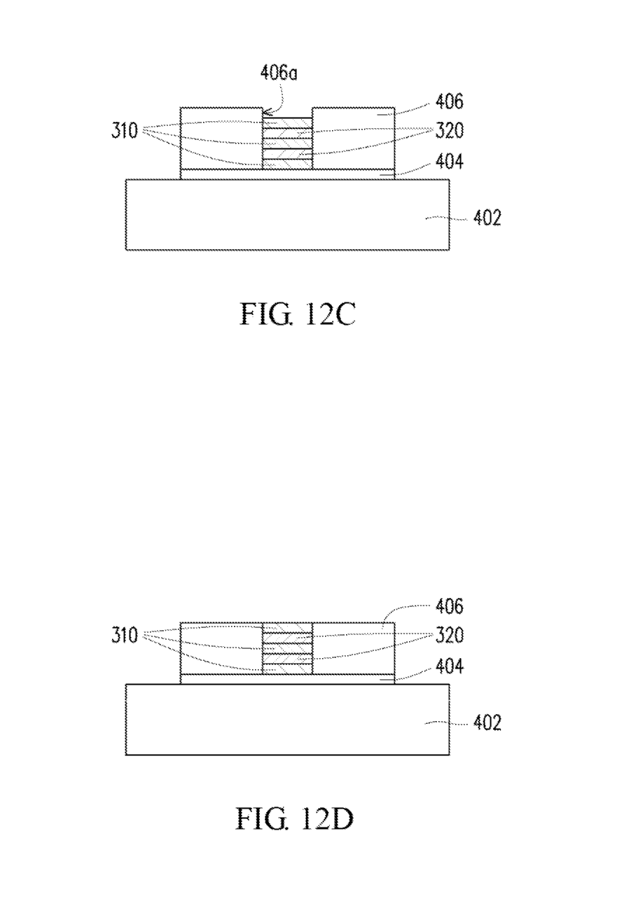

Referring to FIGS. 7A, 7B and 7C, a probe 300 in this embodiment is different from the probe 300 shown in FIGS. 5A, 5B and 5C in that the skin effect layer 330 covers the whole main portion 310. In particular, the skin effect layer 330 completely covers the tip 312, the body 314 and the tail 316 of the main portion 310.

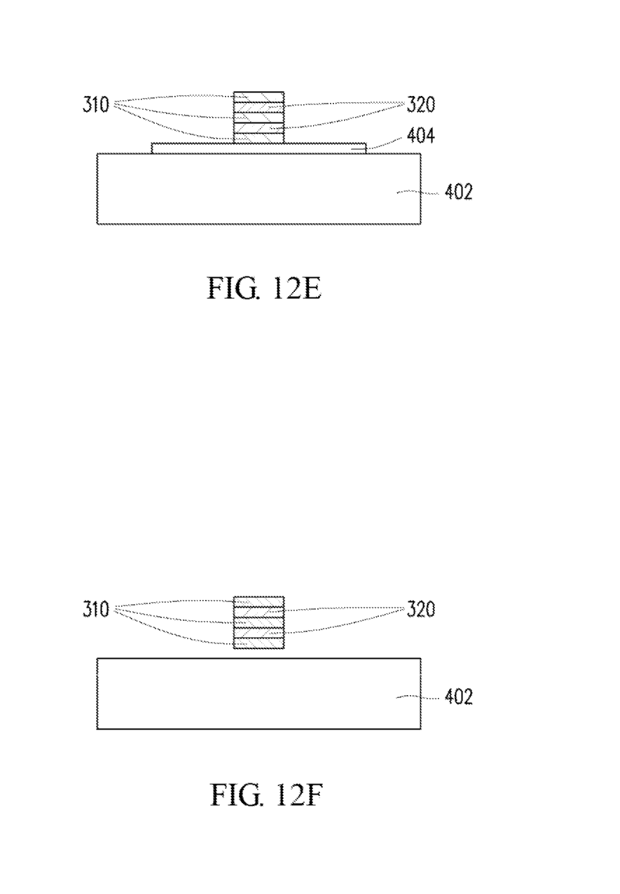

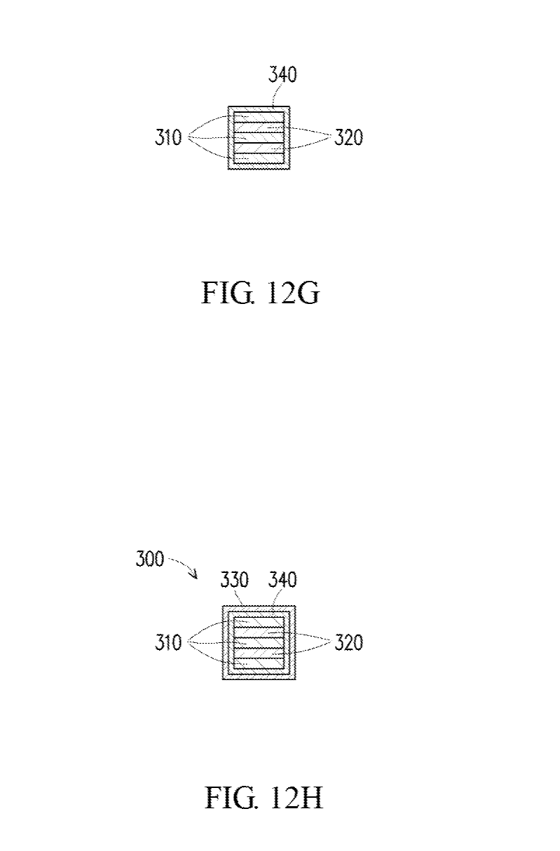

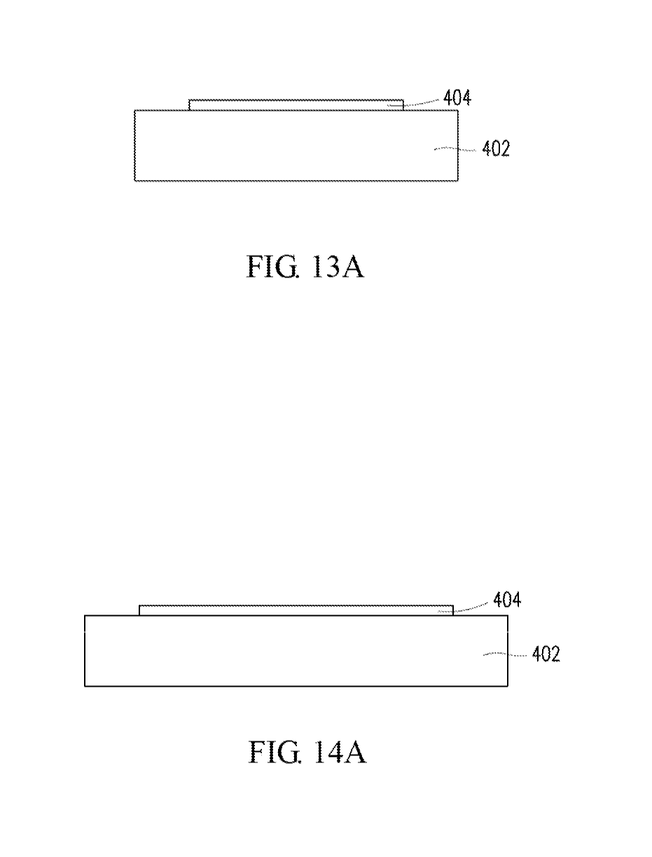

Referring to FIGS. 8A, 8B and 8C, a probe 300 in this embodiment is different from the probe 300 shown in FIGS. 7A, 7B and 7C in that the skin effect layer 330 covers parts of the main portion 310. Besides, the skin effect layer 330 continuously covers the tip 312, the body 314 and the tail 316 of the main portion 310 for providing additional path for electrical currents, so that the electrical currents will be transmitted from the tip 312 to the tail 316 completely.

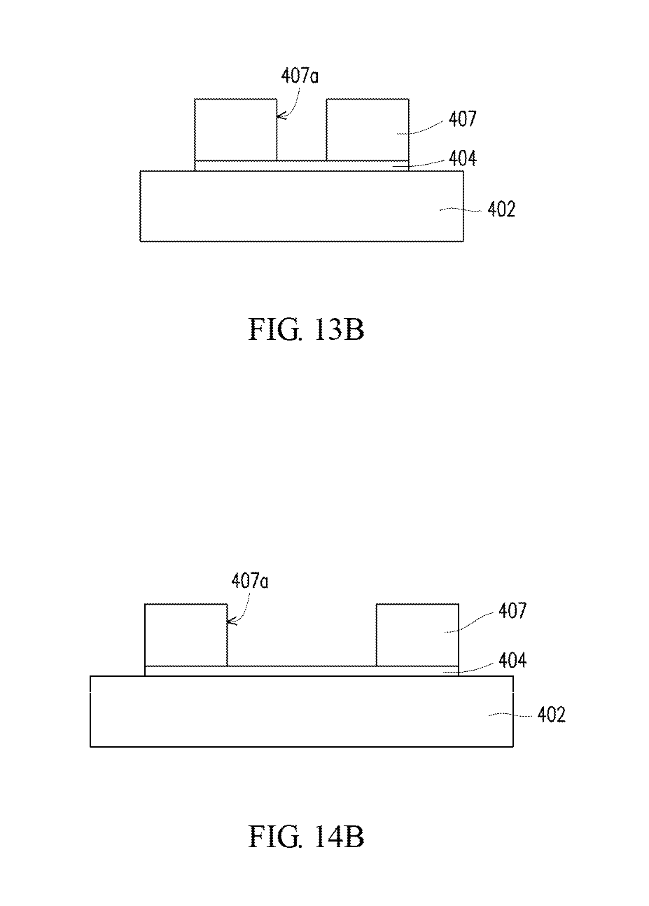

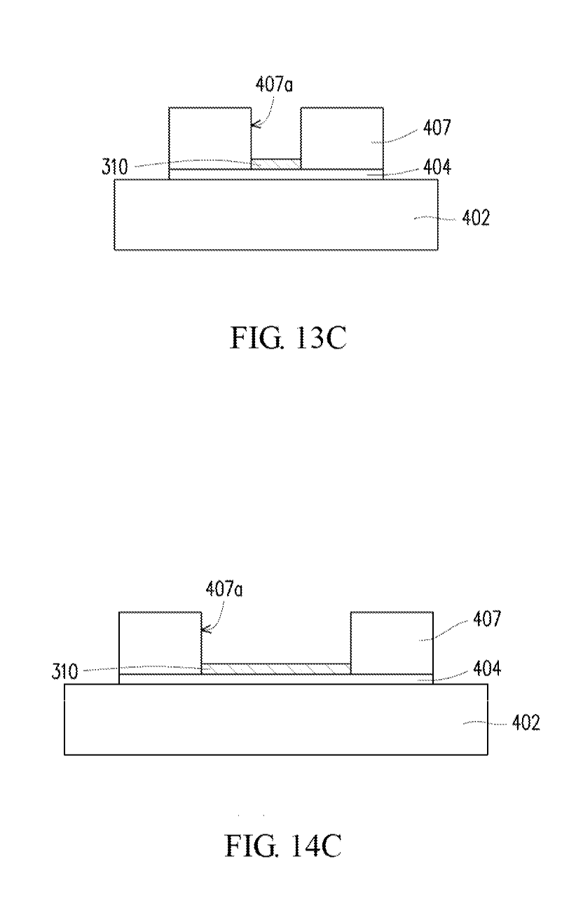

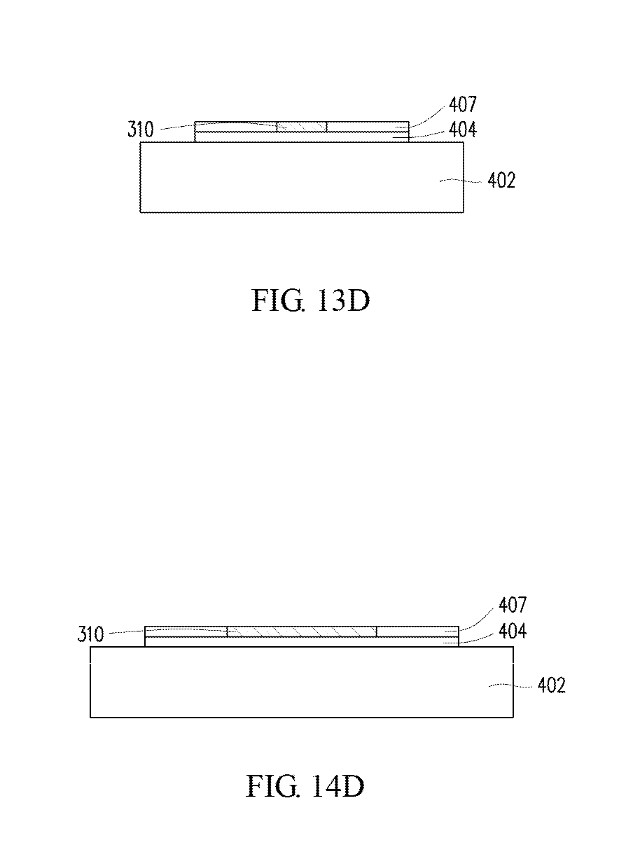

Referring to FIGS. 9A, 9B and 9C, a probe 300 in this embodiment is different from the probe 300 shown in FIGS. 5A, 5B and 5C in that the probe 300 comprises a plurality of main portions 310 and a plurality of conductive portions 320, which are layered alternately. Each of the skin effect layer 330 and the attachment layer 340 of the probe 300 covers the main portions 310 and the conductive portions 320.

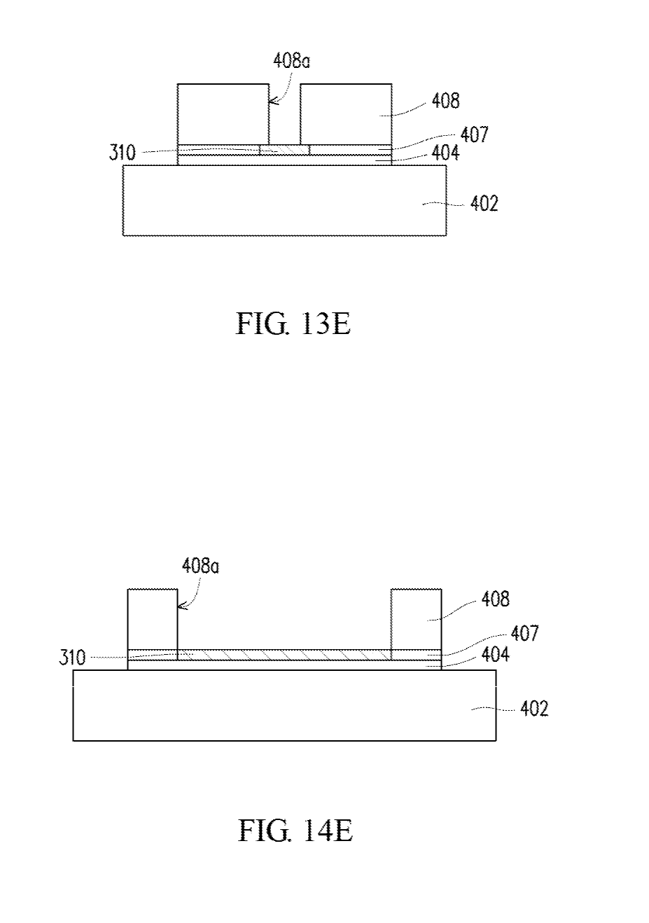

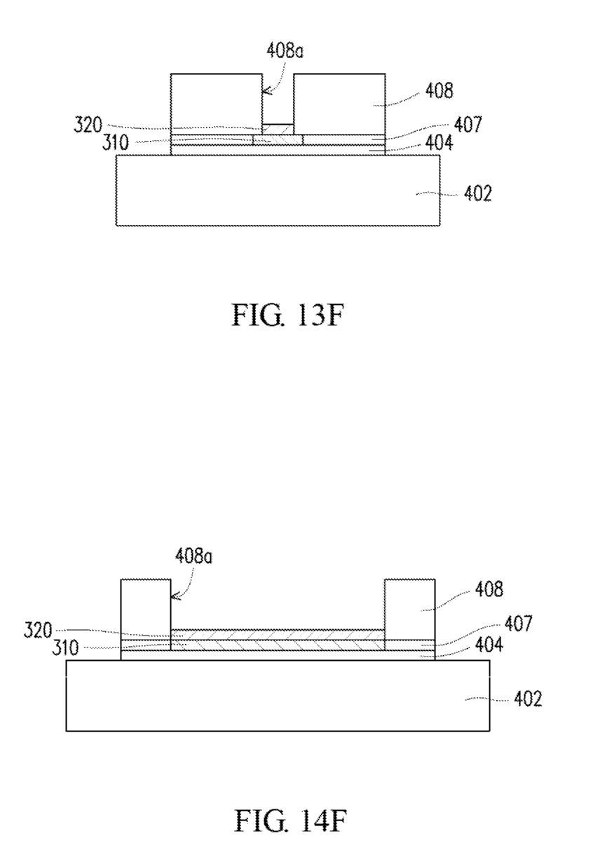

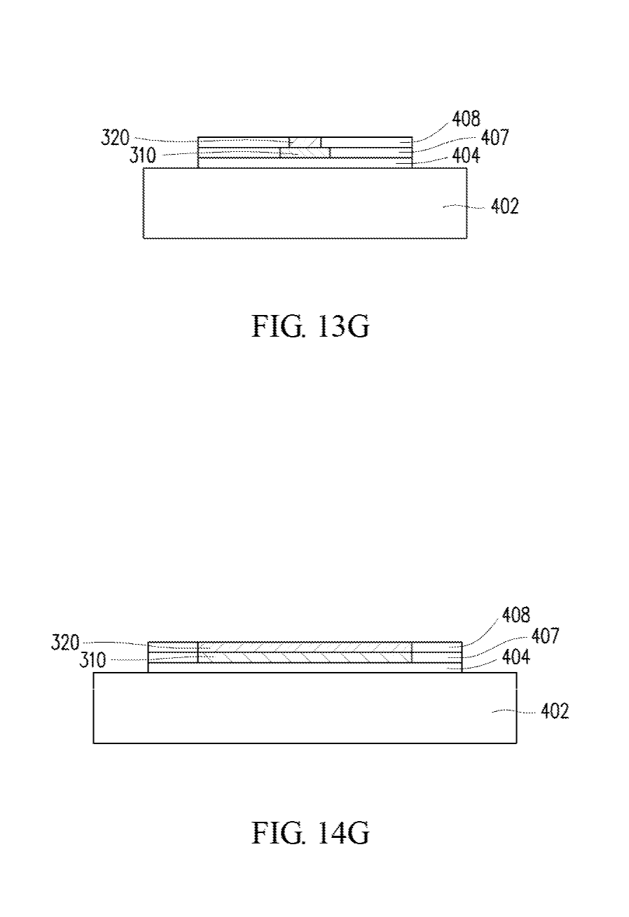

Referring to FIGS. 10A, 10B and 10C, a probe 300 in this embodiment is different from the probe 300 shown in FIGS. 9A, 9B and 9C in that some of the main portions 310 comprise the tip 312, the body 314 and the tail 316 of the probe 300, and the other main portions 310 comprise the body 314 only. The conductive portions 320 are distributed adapting to the main portions 310.

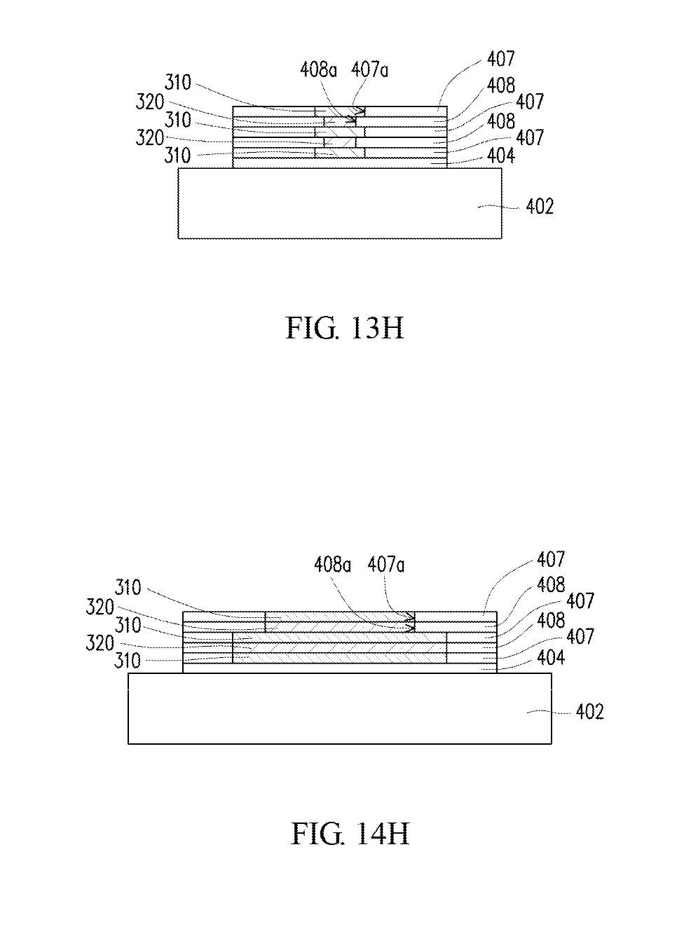

Referring to FIGS. 11A, 11B, 11C and 11D showing a plurality of alternated shapes of the probe 300, the probe 300 shown in FIGS. 5A, 7A, 8A, 9A and 10A can be configured as each of the shapes. The probe 300 shown in FIG. 11A is a kind of vertical buckling probe, i.e. Cobra probe, wherein an offset is provided between the tip 312 and the tail 316, and the body 314 is curved. The probe 300 shown in FIG. 11B is a kind of straight probe. The probe 300 shown in FIG. 11C is another kind of straight probe, wherein the body 314 has a concave 314a for weakening the body 314. The probe 300 shown in FIG. 11D is a kind of spring probe, i.e. Pogo-pin, wherein the body 314 has a section curved continuously to serve as a spring.

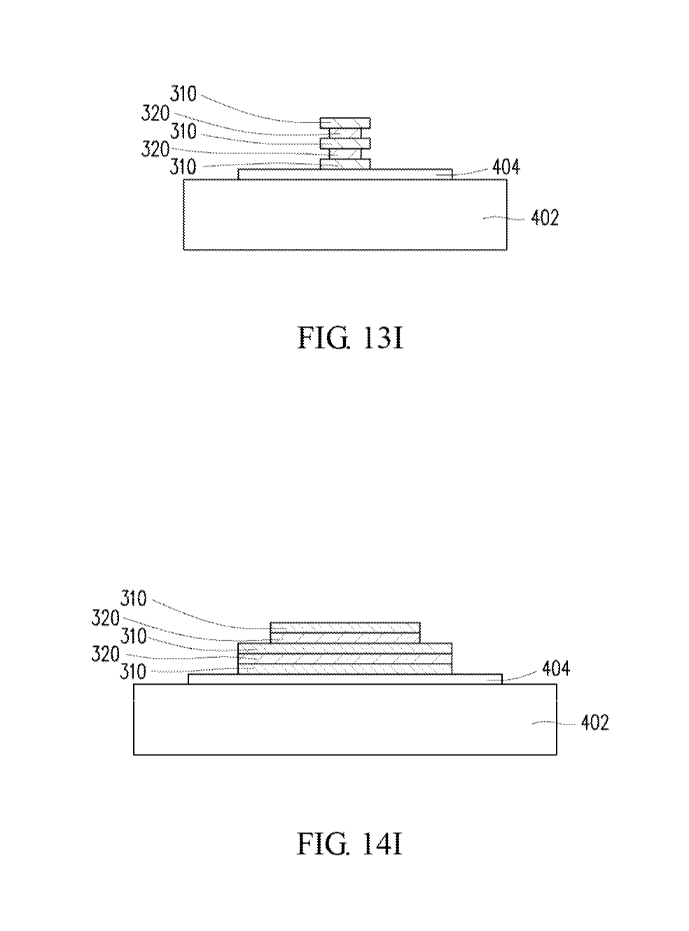

FIGS. 12A-12H are schematic transverse sectional views showing the steps of a method for manufacturing a probe according to an embodiment of the present invention. Referring to FIG. 12A, a step of forming a sacrificial layer 404 on a substrate 402 is shown.

Referring to FIG. 12B, a step of forming a patterned mask 406 on the sacrificial layer 404 is shown. In this embodiment, the patterned mask 406 is a photoresist layer after exposure and development processes. The aforesaid exposure process can be performed by exposing the photoresist layer to light through a photomask to provide the photoresist layer with the same pattern with the photomask. Alternatively, the aforesaid exposure process can be performed by exposing the photoresist layer to laser light which directly provides the predetermined pattern to the photoresist layer.

Referring to FIG. 12C, a step of forming at least one main portion 310 and at least one conductive portion 320 in an opening 406a of the patterned mask 406 by multi-time electroplating. In this embodiment, three main portions 310 and two conductive portions 320 are formed in this step. The main portions 310 and the conductive portions 320 are alternately laminated layer by layer.

Referring to FIG. 12D, a step of flattening the patterned mask 406 and the topmost main portion 310 by a process such as grinding is shown.

Referring to FIG. 12E, a step of removing the patterned mask 406 is shown.

Referring to FIG. 12F, a step of removing the sacrificial layer 404 is shown, so that the main portions 310 and the conductive portions 320 are separated from the substrate 402.

Referring to FIG. 12G a step of forming an attachment layer 340 which covers the main portions 310 and the conductive portions 320 is shown. This step of forming the attachment layer 340 can be performed by chemical plating, electroplating, or sputtering.

Referring to FIG. 12H, a step of forming a skin effect layer 330 which covers at least a part of the conductive portions 320 is shown. In this embodiment, the skin effect layer 330 covers the attachment layer 340, and only a part of the conductive portions 320 will be covered by the skin effect layer 330 because the main portions 310 and the conductive portions 320 are alternately laminated layer by layer. This step of forming the skin effect layer 330 can be performed by chemical plating, electroplating, or sputtering. The thickness of the skin effect layer 330 can be smaller than 5 μm, such that the skin effect layer 330 needs not to be flattened.

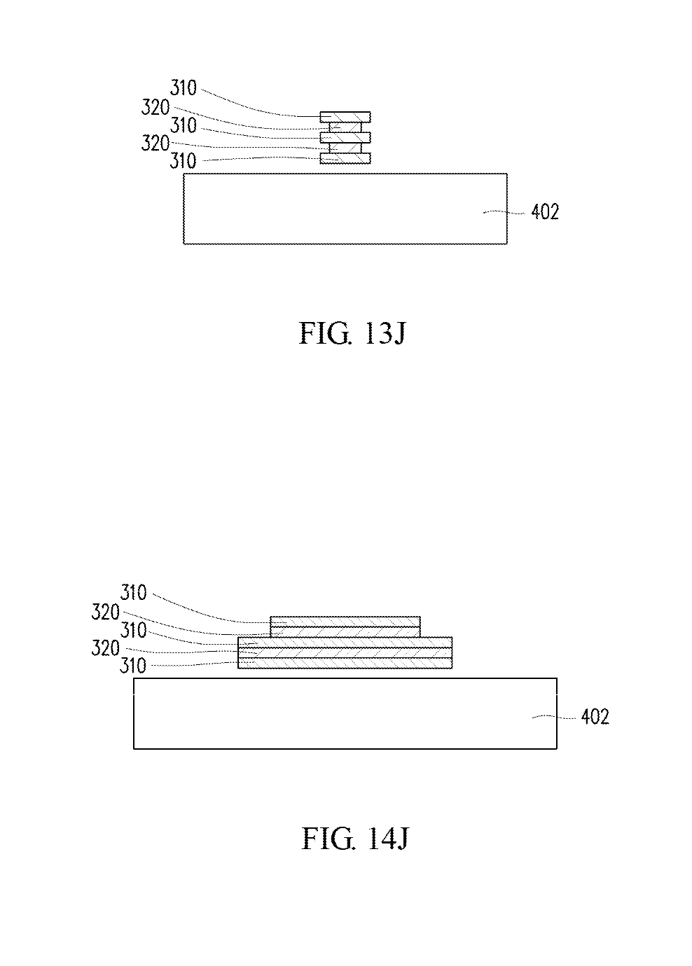

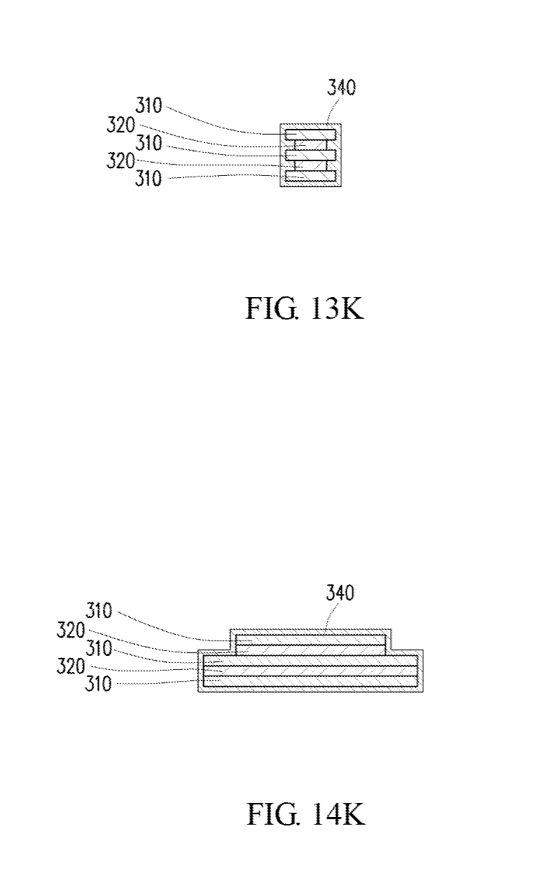

FIGS. 13A-13L are schematic transverse sectional views showing the process of a method for manufacturing a probe according to an embodiment of the present invention. FIGS. 14A-14L are schematic longitudinal sectional views of FIGS. 13A-13L. Referring to FIG. 13A and FIG. 14A, a sacrificial layer 404 is formed on a substrate 402.

Referring to FIG. 13B and FIG. 14B, a first patterned mask 407 is formed on the sacrificial layer 404. In this embodiment, the first patterned mask 407 is a photoresist layer after exposure and development processes.

Referring to FIG. 13C and FIG. 14C, a main portion 310 is formed in a first opening 407a of the first patterned mask 407 by electroplating.

Referring to FIG. 13D and FIG. 14D, a step of flattening the first patterned mask 407 and the main portion 310 by a process such as grinding is shown.

Referring to FIG. 13E and FIG. 14E, a second patterned mask 408 is formed on the first patterned mask 407. In this embodiment, the second patterned mask 408 is a photoresist layer after exposure and development processes.

Referring to FIG. 13F and FIG. 14F, a step of forming a conductive portion 320 in a second opening 408a of the second patterned mask 408 by electroplating is shown. The widths of the main portion 310 and the conductive portion 320 are adjustable by adjusting the widths of the first opening 407a and the second opening 408a. Specifically speaking, the main portion 310 is extended along a path, such as the path P shown in FIG. 11A or the path Q shown in FIG. 11B; the main portion 310 and the conductive portion 320 are different in width perpendicular to the path. In this embodiment, the width of the conductive portion 320 is smaller than the width of the main portion 310. Specifically speaking, the width of the conductive portion 320, which is perpendicular to the path, is smaller than the width of the main portion 310, which is perpendicular to the path.

Referring to FIG. 13G and FIG. 14G a step of flattening the second patterned mask 408 and the conductive portion 320 by a process such as grinding is shown.

Referring to FIG. 13H and FIG. 14H, repeat the aforesaid steps to form two other main portions 310 and another conductive portion 320. It is to be mentioned that in the process of forming the topmost main portion 310 and the topmost conductive portion 320, the positions of the first opening 407a and the second opening 408a can be adjusted for adjusting the positions of the topmost main portion 310 and the topmost conductive portion 320 in a way that the topmost main portion 310 is formed as the body, but not the tip and the tail.

Referring to FIG. 13I and FIG. 14I, the first patterned masks 407 and the second patterned masks 408 are removed.

Referring to FIG. 13J and FIG. 14J, a step of removing the sacrificial layer 404 is shown, so that the main portions 310 and the conductive portions 320 are separated from the substrate 402.

Referring to FIG. 13K and FIG. 14K, a step of forming an attachment layer 340 which covers the main portions 310 and the conductive portions 320 is shown. This step of forming the attachment layer 340 can be performed by chemical plating, electroplating, or sputtering.

Referring to FIG. 13L and FIG. 14L, a step of forming a skin effect layer 330 which covers at least a part of the conductive portions 320 is shown. In this embodiment, the skin effect layer 330 covers the attachment layer 340, and the skin effect layer 330 and the attachment layer 340 cover at least a part of the conductive portions 320. This step of forming the skin effect layer 330 can be performed by chemical plating, electroplating, or sputtering.

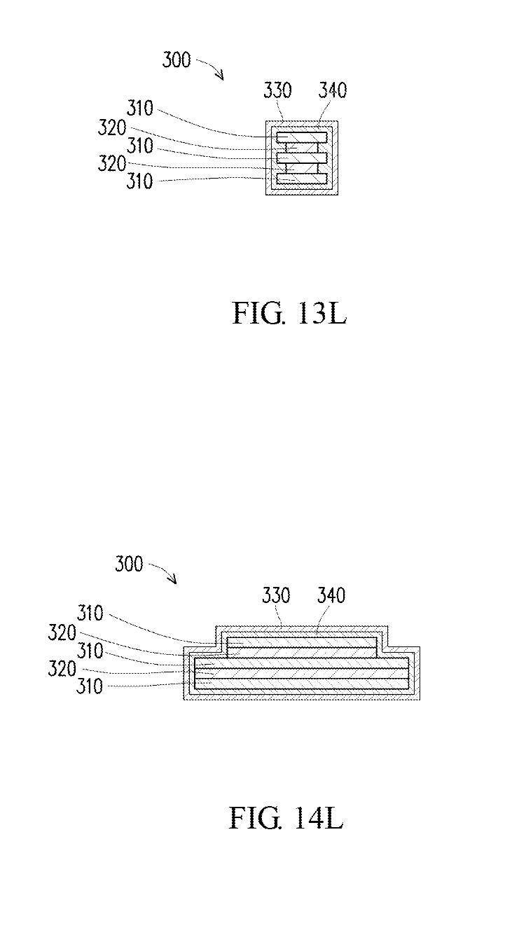

Referring to FIG. 15, in an embodiment the main portions 310 and the conductive portions 320 of a plurality of probes 300, such as the probe 300 shown in FIG. 7C, are formed by the steps similar to those shown in FIGS. 12A-12E. When the main portions 310 are formed, a plurality of connecting portions 502 are simultaneously formed in a way that each connecting portion is connected with a plurality of main portions 310. At the same time, an auxiliary portion 504 can be formed to connect the connecting portions 502. Therefore, after the main portions 310, the conductive portions 320, the connecting portions 502 and the auxiliary portion 504 are formed, the connecting portions 502 can be moved by moving the auxiliary portion 504, so that the main portions 310 and the conductive portions 320 attached to the main portions 310 are moved at the same time. Thereafter, a plurality of skin effect layers can be formed on the main portions 310 and the conductive portions 320, as shown in FIGS. 12G and 12H. Specifically speaking, a plurality of attachment layers 340 (as shown in FIG. 12G) can be formed before the skin effect layers 330 (as shown in FIG. 12H) are formed. The skin effect layers 330 are formed on the attachment layers 340, respectively. Besides, if the skin effect layers 330 and the attachment layers 340 are formed by electroplating, the electrical current for electroplating can be transmitted to the main portions 310 and the conductive portions 320 through the auxiliary portion 504 and the connecting portions 502. Therefore, the probes 300 can be made by batch production by means of the connecting portions 502 and the auxiliary portion 504.

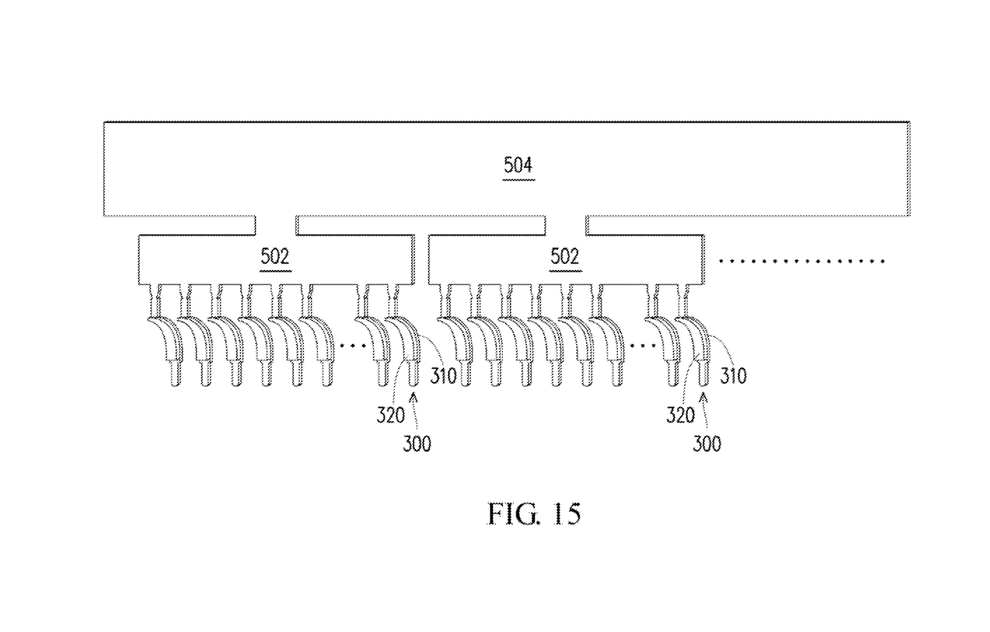

Referring to FIG. 16, a probe 300 in this embodiment is different from the embodiment shown in FIG. 7B in that a contact end 310a of the main portion 310 is exposed. The contact end 310a may be formed by removing a part of the skin effect layer 330 and a part of the attachment layer 340 after the skin effect layer 330 and the attachment layer 340 are formed. The contact end 310a is adapted for contacting a contact of the DUT. The other end of the main portion 310, which is opposite to the contact end 310a, is adapted for contacting a contact of a space transformer of the probe card. For example, sandpaper can be used to grind the parts of the skin effect layer 330 and the attachment layer 340, which are located at the contact end 310a of the main portion 310, so as to expose the contact end 310a of the main portion 310. Because the hardness of the skin effect layer 330 is relatively less, the skin effect layer 330 is unable to effectively break through the oxidation layer of the contact of the DUT, so that the probe is unable to produce obvious scrub mark on the contact of the DUT when probing. Therefore, in this embodiment the parts of the skin effect layer 330 and the attachment layer 340, which are located at the contact end 310a of the main portion 310, are removed, such that the probe may produce relatively more remarkable scrub mark on the contact of the DUT when probing. In this embodiment, the length L1 of the tip 312 of the main portion 310 is less than or equal to 100 μm, and the length L2 of the tail 316 of the main portion 310 is less than or equal to 75 μm.

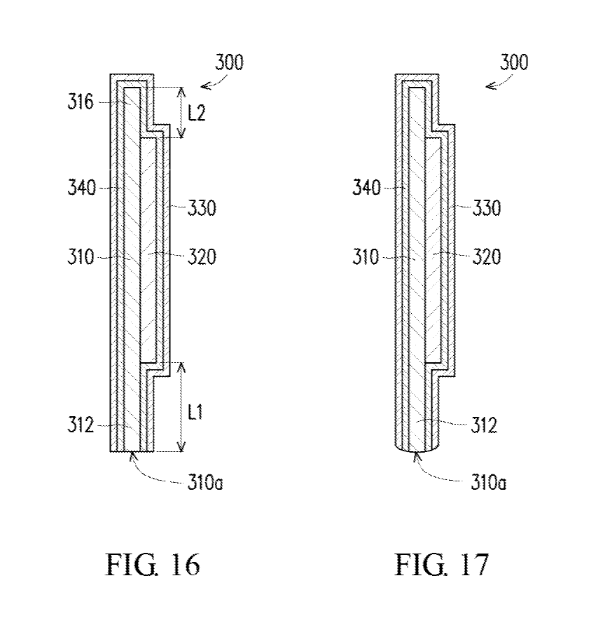

Referring to FIG. 17, in another embodiment the contact end 310a of the main portion 310, and the skin effect layer 330 and the attachment layer 340, which covers the main portion 310, may be arc-shaped by a way of removing the skin effect layer 330 and the attachment layer 340, which is different from that of the embodiment shown in FIG. 16. For example, this embodiment shown in FIG. 17 can use sandpaper different from that used in the embodiment shown in FIG. 16.

The probe 300 of the present invention, such as the probe 300 shown in FIGS. 5A and 5B, can replace the vertical buckling probe 100 so as to be used in the probe head 200 shown in FIG. 4. According to the practical demands, in the situation that the probe 300 is not forced and deformed the conductive portion 320, or even the skin effect layer 330 and the attachment layer 340 as well, may be attached to a part of the tip 312 of the main portion 310. Preferably, the conductive portion 320 is attached to at least a part of the tip 312. The tip 312 is inserted in the lower hole 212 of the lower die 210. The main portion has a section, to which the conductive portion 320 is not attached, and the length of the section, which is defined from the terminal (for contacting the contact of the DUT) of the tip 312 in the direction to the body, is ranged from 5 μm to 200 μm. In this way, the probe has better current carrying capacity than the general probes with equal width to the probe. Specifically speaking, the thickness of the probe 300, including the main portion 310 and the conductive portion 320, or additionally including the skin effect layer 330 and the attachment layer 340 as well, is ranged from 40 μm to 50 μm. If the conductive portion 320 is extended from the body to a part of the tip 312, the probe will have current carrying capacity ranged from 1 A to 1.2 A. For preventing the tip 312 from interference with the inner wall of the lower hole 212 wherein the tip is inserted upon assembling the probe head, the cross-section area of the assembly of the tip 312 and the conductive portion 320 should be smaller than the dimension of the lower hole 212. Further, the probe of the present invention is provided with the aforesaid stopping portion for being abutted against the lower die 210 or the upper die 220 of the probe head 200.

As to the probe of the present invention and the method for manufacturing the probe, the probe has the skin effect layer which may cover the conductive portion partially or completely, or cover the main portion and the conductive portion partially or completely, resulting in additional path for electrical currents. Besides, the skin effect layer can be formed around the periphery of the main portion and the conductive portion after the main portion and the conductive portion are formed, so that the manufacturing process of the probe can be simplified.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A probe for being used in a probe head having a lower die and an upper die, the probe comprising:
a main portion;
a conductive portion stacked on at least a part of the main portion;
an attachment layer covering the main portion and the conductive portion;
a skin effect layer covering the attachment layer; and
a stopping portion for being abutted against the lower die or the upper die;
wherein the main portion comprises a first material; the conductive portion comprises a second material; the skin effect layer comprises a third material; an electrical conductivity of the third material is greater than an electrical conductivity of the second material; the electrical conductivity of the second material is greater than an electrical conductivity of the first material; a hardness of the first material is greater than a hardness of the second material; the hardness of the first material is greater than a hardness of the third material.

2. The probe as claimed in claim 1, wherein the main portion has a tip for being inserted through a lower hole of the lower die, a body connected with the tip, and a tail connected with the body; the conductive portion is attached to at least a part of the tip and at least a part of the body.

3. The probe as claimed in claim 2, wherein the main portion has a section without being attached with the conductive portion, and a length of the section, which is defined from a terminal of the tip in a direction to the body, is ranged from 5 μm to 200 μm.

4. The probe as claimed in claim 1, wherein a thickness of the main portion is ranged from 15 μm to 40 μm.

5. The probe as claimed in claim 1, wherein a thickness of the conductive portion is ranged from 2 μm to 40 μm.

6. The probe as claimed in claim 1, wherein a thickness of the skin effect layer is ranged from 1 μm to 5 μm.

7. The probe as claimed in claim 1, wherein a thickness of the attachment layer is ranged from 0.1 μm to 3 μm.

8. The probe as claimed in claim 1, wherein the main portion has a contact end exposed out of the skin effect layer.

9. The probe as claimed in claim 1, wherein the main portion has a tip, a body connected with the tip, and a tail connected with the body; at least a part of the main portion is covered by the skin effect layer; the skin effect layer covers the tip, the body and the tail of the main portion.

10. The probe as claimed in claim 1, wherein the skin effect layer covers a whole assembly of the main portion and the conductive portion.

11. The probe as claimed in claim 1, comprising:
a plurality of said main portions; and
a plurality of said conductive portions;
wherein the conductive portions and the main portions are alternately laminated layer by layer and covered by the skin effect layer.

12. A method for manufacturing a probe, comprising the steps of:
forming a main portion and a conductive portion stacked on at least a part of the main portion;
forming an attachment layer covering the main portion and the conductive portion; and
forming a skin effect layer covering the attachment layer;
wherein the main portion comprises a first material; the conductive portion comprises a second material; the skin effect layer comprises a third material; an electrical conductivity of the third material is greater than an electrical conductivity of the second material; the electrical conductivity of the second material is greater than an electrical conductivity of the first material; a hardness of the first material is greater than a hardness of the second material; the hardness of the first material is greater than a hardness of the third material.

13. The method as claimed in claim 12, wherein the step of forming the main portion and the conductive portion comprises the steps of:
forming the main portion on a sacrificial layer that is disposed on a substrate;
forming the conductive portion on the main portion; and
removing the sacrificial layer so that the main portion and the conductive portion are separated from the substrate.

14. The method as claimed in claim 13, wherein the step of forming the main portion comprises the steps of:
forming a first patterned mask on the substrate;
forming the main portion in a first opening of the first patterned mask by electroplating; and
flattening the first patterned mask and the main portion.

15. The method as claimed in claim 14, wherein the step of forming the conductive portion comprises the steps of:
forming a second patterned mask on the first patterned mask;
forming the conductive portion in a second opening of the second patterned mask by electroplating; and
flattening the second patterned mask and the conductive portion.

16. The method as claimed in claim 13, wherein the step of forming the main portion and the conductive portion comprises the step of:
forming a plurality of said main portions and a plurality of said conductive portions in a way that the main portions and the conductive portions are alternately laminated layer by layer; the skin effect layer covers at least a part of the conductive portions.

17. The method as claimed in claim 12, further comprising the step of removing a part of the skin effect layer after forming the skin effect layer so that a contact end of a tip of the main portion is exposed.

18. The method as claimed in claim 12, wherein a plurality of said main portions, a plurality of said conductive portions, a plurality of connecting portions and an auxiliary portion are formed in the step of forming the main portion and the conductive portion; each of the conductive portions is stacked on at least a part of a corresponding said main portion; each of the main portions is connected with a corresponding said connecting portion; each of the connecting portions is connected with the auxiliary portion; a plurality of said skin effect layers are formed in the step of forming the skin effect layer; each of the skin effect layers covers at least a part of a corresponding said conductive portion.

19. The method as claimed in claim 18, wherein the main portions, the connecting portions and the auxiliary portion are formed simultaneously in the step of forming the main portions.
